(19) United States
(12) Patent Application Publication
(10) Pub. No.: US 2021/0101486 A1
(43) Pub. Date: Apr. 8, 2021

(54) SYSTEM AND METHOD FOR SOLAR CELL ARRANGEMENT ON THE DASHBOARD OF A VEHICLE

(71) Applicant: Aperta Motors, Corp., San Diego, CA (US)

(72) Inventors: Jason HILL, Long Beach, CA (US); Steve FAMBRO, Carlsbad, CA (US); Chris ANTHONY, San Diego, CA (US); Darren McKEAGE, Carlsbad, CA (US)

(73) Assignee: Aptera Motors, Corp., San Diego, CA (US)

(21) Appl. No.: 17/063,529

(22) Filed: Oct. 5, 2020

Related U.S. Application Data
(60) Provisional application No. 62/910,656, filed on Oct. 4, 2019.

(51) Int. Cl. B60L 8/00; B60K 37/00; H02S 30/00; H02S 40/20; G02B 1/11; B60L 50/60; H02S 40/38

(52) U.S. Cl. CPC B60L 8/003; B60K 37/00; H02S 30/00; H02S 40/38; G02B 1/11; B60L 50/60; H02S 40/20

(57) ABSTRACT

Vehicles having a plurality of solar cells arranged on a dashboard of the vehicle. The solar cells are arranged at an acute angle relative to a longitudinal axis of the dashboard, and may have an arcuate shape along the longitudinal axis of the dashboard. The solar cells may have an irregular octagon shape and may be more flexible along one axis of symmetry relative to the other axis of symmetry.

### TECHNICAL FIELD

Embodiments disclosed herein are generally related to vehicles, and more particularly to solar powered vehicles.

### BACKGROUND

In an effort to reduce emissions, automobile manufacturers are looking for alternative methods to power vehicles, such as automobiles. One form of alternative power source is solar power. To make use of solar power, solar cells are typically used in conjunction with on-board batteries, typically a traction battery for propulsion and an auxiliary battery for use by instrument panels, operator interfaces, I/O ports, and the like. Multiple solar cells can be affixed to the exterior surfaces of the vehicle to harvest energy from the sun. That energy is then stored in batteries on the vehicle for use as an alternative to emission-generating fuel to propel the vehicle.

While the sun generates a significant amount of solar energy, modern solar cell technology is unable to harness the majority of that energy. Thus, manufacturers attach the solar cells to the vehicle in an efficient manner that can place the most cells into the smallest area on the exterior body of the vehicle. Since alternative fuel vehicles require a significant amount of energy to maintain the standard of quality and operability set by fossil-fuel based vehicles, manufacturers are looking to utilize the greatest available space on the vehicle in order to maximize the amount of harvested solar energy. Spaces on and inside the vehicle previously unused or previously reserved for other features or functions are now potential sites for expanding the number of solar cells used for harvesting solar energy for vehicle propulsion.

### BRIEF DESCRIPTION OF THE DRAWINGS

For a more complete understanding of the present disclosure and certain features thereof, reference is now made to the following description, in conjunction with the accompanying figures briefly described as follows:

FIG. 1 presents a top plan view of a solar cell arrangement on the dashboard of a vehicle in accordance with one example embodiment of the disclosure.

FIG. 2 is a top plan view of a solar cell for use with the solar cell arrangement on the dashboard of a vehicle in accordance with one example embodiment of the disclosure.

FIG. 3 is a side elevation view of a solar cell used in the solar cell arrangement on the dashboard of a vehicle in accordance with one example embodiment of the disclosure.

FIG. 4 is a top plan view of a solar cell arrangement on the rear dashboard of a vehicle in accordance with one example embodiment of the disclosure.

FIG. 5A is a side view in cross section of a solar cell arrangement on the dashboard of a vehicle in accordance with one example embodiment of the disclosure.

FIG. 5B is a side view in cross section of a solar cell arrangement on the dashboard of a vehicle in accordance with one example embodiment of the disclosure.

FIG. 5C is a side view in cross section of a solar cell arrangement on the dashboard of a vehicle in accordance with one example embodiment of the disclosure.

### DETAILED DESCRIPTION OF THE EXAMPLE EMBODIMENTS

Example embodiments of a solar cell arrangement on the dashboard of a vehicle will be described more fully hereinafter with reference to the accompanying drawings, in which example embodiments are shown. The concepts claimed and described herein may, however, be embodied in many different forms and should not be construed as limited to the example embodiments set forth herein; rather, these embodiments are provided so that this disclosure will be thorough and complete, and will fully convey the scope of the claimed invention to those skilled in the art. Like numbers refer to like, but not necessarily the same, elements throughout.

Certain dimensions and features of the example solar cell arrangement are described herein using the term “approximately.” As used herein, the term “approximately” indicates that each of the described dimensions is not a strict boundary or parameter and does not exclude functionally similar variations therefrom. Unless context or the description indicates otherwise, the use of the term “approximately” in connection with a numerical parameter indicates that the numerical parameter includes variations that, using mathematical and industrial principles accepted in the art (e.g., rounding, measurement or other systematic errors, manufacturing tolerances, etc.), would not vary the least significant digit.

In addition, certain relationships of the solar cell arrangement are described herein using the term “substantially.” As used herein, the terms “substantially” and “substantially equal” indicates that the relationship or equal relationship is not a strict relationship and does not exclude functionally similar variations therefrom. Unless context or the description indicates otherwise, the use of the term “substantially” or “substantially equal” in connection with two or more described dimensions or elements indicates that the equal relationship between the dimensions or elements includes variations that, using mathematical and industrial principles accepted in the art (e.g., rounding, measurement or other systematic errors, manufacturing tolerances, etc.), would not vary the least significant digit of the dimensions or elements. As used herein, the term “substantially constant” indicates that the constant relationship is not a strict relationship and does not exclude functionally similar variations therefrom. As used herein, the term “substantially parallel” indicates that the parallel relationship is not a strict relationship and does not exclude functionally similar variations therefrom. As used herein, the terms “substantially perpendicular” and “substantially orthogonal” indicate that the perpendicular relationship is not a strict relationship and does not exclude functionally similar variations therefrom.

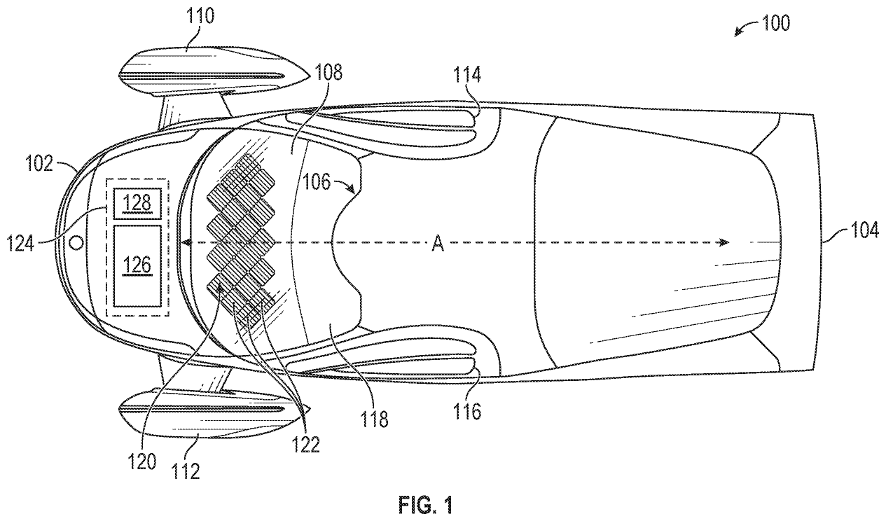

FIG. 1 is a top plan view a solar cell arrangement on the dashboard of a vehicle 100 in accordance with one example embodiment of the disclosure. The term vehicle, as used herein, may refer to any suitable type of automobile, including a consumer vehicle (e.g., sedan, sport utility vehicle, etc.), commercial vehicle (e.g., delivery truck, tractor trailer, etc.), and/or a recreational vehicle. As discussed above, each of the one or more panels that form the dashboard solar array of the solar powered vehicle may include one or more solar cells.

Referring to FIG. 1, the solar powered vehicle 100 can include a front end 102 and a distal rear end 104. A longitudinal axis A for the vehicle 100 can extend from the front end 102 to the rear end 104. The vehicle 100 also includes a vehicle interior 106. The vehicle interior 106 can include one or more passenger seats (not shown), a steering wheel (not shown), a dashboard 108 and other components found in the interior of conventional automobiles and known to those of ordinary skill in the art.

The vehicle 100 can also include wheels for moving the vehicle along a road surface. In one example, the vehicle 100 can include a first front wheel 110 positioned along one lateral side of the vehicle and a second front wheel 112 positioned along a second lateral side of the vehicle opposite the first lateral side. In an alternate embodiment, the vehicle 100 can only include a single front wheel that is positioned centrally or substantially centrally between the first and second lateral sides of the vehicle 100 and along the longitudinal axis A.

The vehicle 100 can also include one or more rear wheels (not shown). In one example, the vehicle 100 can include a single rear wheel centrally or substantially centrally positioned between the first lateral side and the second lateral side and along the longitudinal axis A of the vehicle 100. In another example embodiment, the vehicle 100 can include a two rear wheels, with a first rear wheel positioned along the first lateral side of the vehicle and a second rear wheel positioned along the second lateral side of the vehicle.

The vehicle 100 can also include one or more doors for accessing the vehicle interior 106. In one example, the vehicle includes a first door 114 positioned along the first lateral side of vehicle 100 and a second door 116 positioned along the second lateral side of the vehicle 100. In other examples, more or less than two doors 114, 116 can be provided on the vehicle 100. Each door 114, 116 can be hingedly coupled to the vehicle frame and can be adjusted from an open position, that provides access to the vehicle interior 106 from the exterior of the vehicle 100, to a closed position, that prevents or limits access to the vehicle interior 106 from the exterior of the vehicle 100. The vehicle 100 can also include a windshield 118 disposed at least partially above the dashboard 108.

The vehicle 100 can include a group 120 of solar cells 122 disposed along the top surface of the dashboard 108. In one example, the number of solar cells 122 disposed on the dashboard 108 can be greater than 5 and preferably greater than 10 and more preferably greater than 15. In certain examples, twenty solar cells 122 are in the group 120 of solar cells 122 disposed on the dashboard 108. However, greater or lesser numbers of solar cells 122 may be included in the arrangement 120 and the number can be affected by a change in the size and/or shape of each individual cell 122 and the top surface area of the dashboard 108. Each of the solar cells 122 may be coupled to the dashboard 108 of the vehicle 100 described above with the use of adhesive or another bonding material.

In some embodiments, a group 120 of solar cells 122 is disposed along one or more select portions of the dashboard 108 depending on the geometry of the dashboard. In one example, a dashboard 108 may have a raised portion covering an instrument cluster with solar cells disposed along the top surface of this raised portion. In another example, a dashboard 108 may have a recessed portion where the dashboard meets a windshield with solar cells disposed within this recessed portion, which in some configurations may hide the solar cells from the occupants of the vehicle. Any dashboard geometry may be adapted to accommodate a group 120 of solar cells 122.

The vehicle 100 can also include a compartment 124 that may be disposed adjacent to the front end 102 of the vehicle between dashboard 108 and the front end 102. The compartment 124 can include a traction battery 126, an electric motor 128, and at least a portion of a vehicle drive system (not shown) (e.g., transmission, drive shaft, differential, etc.). Although the compartment 124 is depicted as being disposed between the front end 102 and the vehicle interior 106, in other example embodiments, the compartment 124 could be disposed between the rear end 104 and the interior 106, or disposed in any other position between the front end 102 and rear end 104. The traction battery 126 is electrically coupled, either directly or indirectly, to the group 120 of solar cells 122 on the dashboard 108 such that the generation of electricity by the harvesting of solar energy by the group 120 is transmitted to and stored in the traction battery 126. The traction battery 126 is also electrically coupled, either directly or indirectly, to the electric motor 128. The electric motor 128 is electromechanically coupled, via the vehicle drive system, to one or more of the first front wheel 110, the second front wheel 112, and/or the one or more rear wheels. Therefore, the solar energy harvested by the group 120 of solar cells 122 is stored in the traction battery 126, and that energy is subsequently used for propulsion of the vehicle 100 by the electric motor 128 through the one or more wheels. By positioning the group 120 of solar cells 122 on the dashboard 108 of the vehicle 100 and electrically coupling the group 120 to the traction battery 126 to provide energy to the electric motor 128 to drive the one or more wheels, the drive range of the vehicle can be increased based on the solar energy captured by the group 120, which may be stored by the traction battery 126. In certain example embodiments, the drive range can be increased substantially. For example, based solely on the group 120 of solar cells 122 feeding electrical power to the traction battery 126, the drive range of the vehicle 100 can be increased by more than one mile, and preferably more than three miles, and more preferably more than 5-20 miles each day.

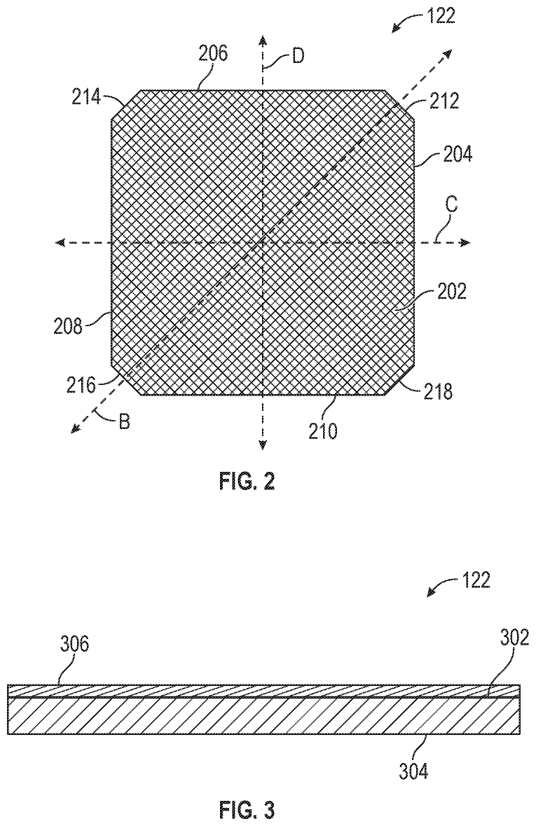

FIG. 2 is a top plan view of a solar cell 122 for use in the solar cell arrangement for the group 120 of solar cells 122 on the dashboard 108, in accordance with one example embodiment of the disclosure. Referring now to FIGS. 1 and 2, in one example, each solar cell 122 can have a generally rectangular shape with the corners either cut off or radiused to reduce the potential for breaking the corner areas of the solar cell 122, which tend to be weak points. The example solar cell 122 of FIG. 2 is an in irregular octagon created by removal of the corners of a generally rectangular (e.g., square) cell 122. For example, the solar cell 122 can have a cell body 202 that has a first long edge 204, a second long edge 206, a third long edge 208, and a fourth long edge 210. The first long edge 204 and the third long edge 208 are parallel or substantially parallel to one another and orthogonal or substantially orthogonal to the second long edge 206 and the fourth long edge 210.

In certain examples, the solar cell 122 can have corners at the junction of the first long edge 204 and second long edge 206, the second long edge and the third long edge 208, the third long edge 208 and the fourth long edge 210, and the fourth long edge 210 and the first long edge 204. In other examples, the solar cell 122 can include a first short edge 212 extending from the first long edge 204 to the second long edge 206, a second short edge 214 extending from the second long edge 206 to the third long edge 208, a third short edge 216 extending from the third long edge 208 to the fourth long edge 210, and a fourth short edge 218 extending from the fourth long edge 210 to the first long edge 204.

The solar cell 122 can have an axis of symmetry B that bisects the first corner and third corner or first short edge 212 and the third short edge 216, an axis of symmetry E that bisects the second corner and fourth corner or the second short edge 214 and the fourth short edge 218, an axis of symmetry C that bisects the first long edge 204 and the third long edge 208, and an axis of symmetry D that bisects the second long edge 206 and the fourth long edge 210. The solar cell 122 has limited flexibility along its axes of symmetry C and D. Along the axes of symmetry B and E, the solar cell 122 has greater flexibility than along each of its axes of symmetry C and D. In certain examples, the solar cell 122 is at least 30% more flexible along the axes of symmetry B and E than along the axes of symmetry C and D.

In one example, given the improved flexibility along the axes of symmetry B and E, the solar cells are applied on the dashboard 108 at an acute angle greater than zero degrees to about forty-five degrees, or substantially at forty-five degrees to the longitudinal axis A of the vehicle 100. In this forty-five degree offset, one of the short edges 212-218 faces the front end 202 of the vehicle 100 and another one of the short edges 212-218 faces the rear 204 of the vehicle 100. In this layout, one of the axes of symmetry B and E is parallel or substantially parallel to the longitudinal axis A of the vehicle 100 and the other one of the axes of symmetry B and E is orthogonal or substantially orthogonal to the longitudinal axis A of the vehicle. Further, in this forty-five degree offset, each of the long edges 204-210 extend at a forty-five degree offset to the longitudinal axis A of the vehicle. In this layout, additional solar cells 122 are applied such that one of the short edges 212-218 of a second solar cell 122 are placed adjacent one of the short edges 212-218 of the first solar cell 122. This layout results in a diamond or argyle design for the solar cells 122 along the surface of the dashboard 108 of vehicle 100. In an alternative embodiment, the solar cells 122 can be applied to the dashboard with the long edges 204-210 being parallel and orthogonal to the longitudinal axis A of the vehicle 100.

In one example, at least one solar cell 122 in the array of solar cells 120 has an arcuate shape along a longitudinal axis of the dashboard 108.

In some embodiments, the group 120 of solar cells 122 include solar cells of varying size and shape. For example, the solar cells 122 at the edges of the group 122 may be smaller than the solar cells 122 toward the center of the group so as to maximize the surface area of the dashboard 108 that is covered in solar cells.

FIG. 3 is a side elevation view of a solar cell 122 included in the solar cell arrangement of the group 120 of solar cells 122 on the dashboard 108, in accordance with one example embodiment of the disclosure. Referring now to FIGS. 1 and 3, each of the solar cells 122 can include a top surface 302 and an opposing bottom surface 304. In certain example, one of a number of coating materials 306 known to those of ordinary skill in the art may be applied to the top surface 302 of the solar cells 122 to operate as an anti-reflective coating. The coating may be applied in the form of a curable liquid that is poured or painted on the solar cells, an adhesive sheet adhered to the solar cells, a film deposited during or after the solar cell is manufactured, an anti-reflective glass or plastic positioned on top of the group of solar cells, or another suitable application method. The coating material 306 is configured to reduce reflected solar energy off the top surface 302 by, for example, modifying the refractive index of the outer-most surface of the solar cell such that it improves the energy capture performance of the solar cell 122. The coating material 306 may include silicon nitrides, titanium oxides, silicon dioxides, titanium dioxides, boron nitrides, zinc oxides, diamond-like carbon films, a combination thereof, and/or any other coating known in the art that is suitable as an anti-reflective coating. In certain examples, applying the coating material to the solar cell 122 improves energy capture performance by at least approximately 5% and preferably by at least approximately 10%, and more preferably by at least approximately 15% over uncoated solar cells 122.

In addition, applying the coating material 306 to the top surface 302 of the solar cell 122 can also reduce the amount of reflected visible light that would normally reflect off the top surface 302 and impair a passenger's visibility. Coating material 306 may be single- or multi-layered and selected from a particular material or combination or materials to tune the amount of visible light reflected. In certain examples, applying the coating material 306 to the solar cell 122 reduces the amount of visible light reflected off of the top surface 302 of the solar cell 122 by at least approximately 20%, and preferably at least approximately 40%, and more preferably at least approximately 50% over the amount of reflected light from the top surface 302 of uncoated solar cells 122.

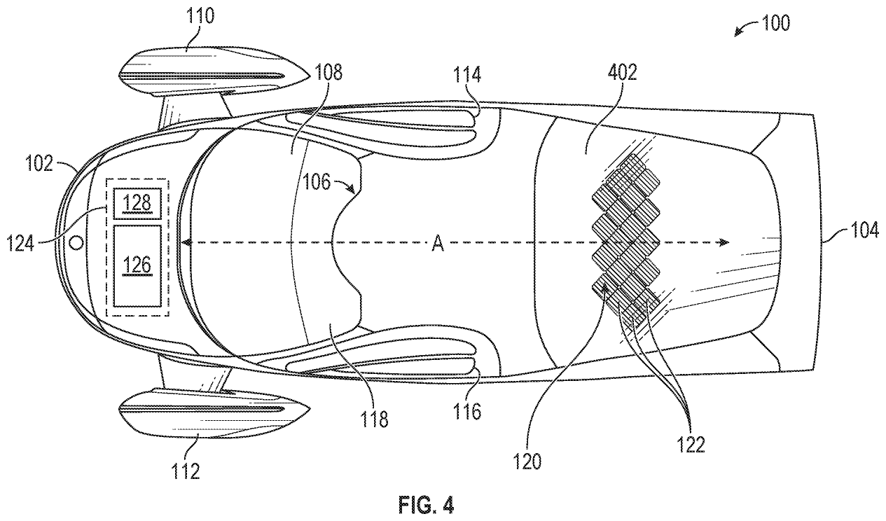

As shown in FIG. 4, and in a similar manner to the embodiments described above in the context of a group of solar cells on a dashboard, the vehicle 100 can also include a group 120 of solar cells 122 in the interior of the vehicle beneath the rear windshield 402. In some embodiments, the solar cells may be located on a rear shelf, perhaps behind seating, or on the floor of a rear storage area. In some of these embodiments, the coating may include a protective layer, or a protective layer may be placed or formed to the coating, to protect the solar cells. The protective layer may include texturing, such as ribs between the solar cells, to limit the movement of objects placed in the storage area.

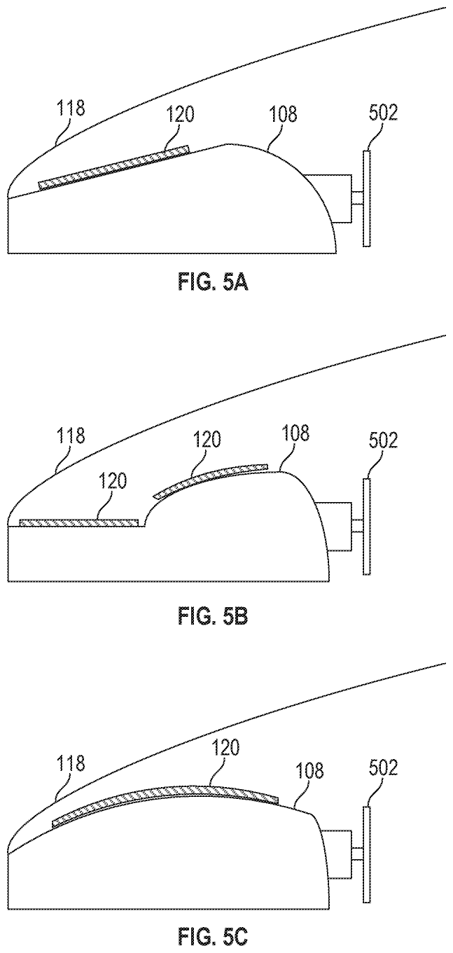

As shown in FIG. 5A-5C, the vehicle can include one or more groups 120 of solar cells 122 on the dashboard 108 selectively positioned and shaped to accommodate the shape of the dashboard 108. Groups 120 of solar cells 122 may be positioned forward of a steering wheel 502 such that the driver of the vehicle cannot see the solar cells when facing windshield 118.

The vehicle 100 can also include any other components found in conventional automobiles. These components are known to those of ordinary skill in the art and are within the capability of those skilled in the art to add to the vehicle 100 as desired and are thus considered part of this disclosure. Though the disclosed examples include particular arrangements of a number of parts, components, features, and aspects, the disclosure is not limited to only those examples or arrangements. Any one or more of the parts, components, features, and aspects of the disclosure can be employed alone or in other arrangements of any two or more of the same.

Although certain features, functions, components, and parts of the solar powered vehicle 100 have been described herein in accordance with the teachings of the present disclosure, the scope of coverage of this patent is not limited thereto. On the contrary, this patent covers all embodiments of the teachings of the disclosure that fairly fall within the scope of permissible equivalents.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language generally is not intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A vehicle comprising:
a dashboard;
a vehicle body;
a plurality of wheels movably coupled to the vehicle body;
an electric motor electromechanically coupled to one or more of the plurality of wheels;
a traction battery electrically coupled the electric motor; and
an array of solar cells disposed along a top surface of the dashboard, wherein each solar cell in the array of solar cells is electrically coupled to the traction battery.

2. The vehicle of claim 1, wherein at least one long edge of at least one solar cell in the array of solar cells is disposed at an acute angle to a longitudinal axis of the vehicle body, wherein the acute angle is greater than zero degrees to about forty-five degrees.

3. The vehicle of claim 2, wherein the acute angle is substantially forty-five degrees.

4. The vehicle of claim 2, wherein all of the solar cells in the array of solar cells have at least one long edge that is disposed at the acute angle to the longitudinal axis.

5. The vehicle of claim 1, wherein each solar cell further comprises an anti-reflective coating.

6. The vehicle of claim 5, wherein the anti-reflective coating increases an amount of solar energy capture by each of the solar cells in the array of solar cells between 10-50%.

7. The vehicle of claim 1, wherein the dashboard is a rear dashboard positioned on a rear shelf behind one or more rear seats of the vehicle.

8. The vehicle of claim 1, wherein the dashboard is a rear dashboard positioned on a floor of a rear storage area.

9. The vehicle of claim 8, wherein the array of solar cells further comprise a textured protective coating layer configured to limit movement of objects placed in the rear storage area.

10. The vehicle of claim 1, wherein at least one solar cell in the array of solar cells has an arcuate shape along a longitudinal axis of the dashboard.

11. The vehicle of claim 1, wherein the array of solar cells include solar cells of varying size and shape.

12. A dashboard for installation in a vehicle, the dashboard comprising an array of solar cells disposed along a top surface of the dashboard, wherein each solar cell in the array of solar cells is configured to be electrically coupled to a traction battery.

13. The dashboard of claim 12, wherein at least one solar cell in the array of solar cells has at least one long edge that is disposed at an acute angle relative to a longitudinal axis of the vehicle, wherein the acute angle is greater than zero degrees to about forty-five degrees.

14. The dashboard of claim 12, wherein each solar cell further comprises an anti-reflective coating.

15. The dashboard of claim 14, wherein the anti-reflective coating increases an amount of solar energy capture by each of the solar cells by approximately 15%.

16. A method of manufacturing a vehicle, the method comprising:
providing a dashboard;
attaching an array of solar cells to a surface of the dashboard, wherein at least a first solar cell in the array of solar cells has at least one long edge disposed at an acute angle relative to a longitudinal axis of the dashboard, wherein the acute angle is greater than zero degrees to about forty-five degrees; and
placing the dashboard into the vehicle.

17. The method of claim 16, further comprising:
applying an anti-reflective coating to each solar cell in the array of solar cells.

18. The method of claim 17, wherein the anti-reflective coating increases an amount of solar energy capture by each of the solar cells in the array of solar cells by approximately 15%.

19. The method of claim 16, wherein the step of placing the dashboard into the vehicle comprises integrating the dashboard into the vehicle behind a steering wheel for capturing solar energy through a forward windshield.

20. The method of claim 16, wherein the dashboard is a rear dashboard, and the step of placing the dashboard into the vehicle comprises integrating the rear dashboard into the vehicle behind one or more rear seats for capturing solar energy through a rear windshield.
